(19) United States
(12) Patent Application Publication
(10) Pub. No.: US 2010/0090310 A1
(43) Pub. Date: Apr. 15, 2010

(54) BIPOLAR TRANSISTOR AND METHOD FOR FABRICATING THE SAME

(76) Inventor: DO-HUN KIM, GANGNAM-GU (KR)

Correspondence Address: SHERR & VAUGHN, PLLC, 620 HERNDON PARKWAY, SUITE 320, HERNDON, VA, 20170, US

(21) Appl. No.: 12/568,793

(22) Filed: Sep. 29, 2009

(30) Foreign Application Priority Data
Oct. 13, 2008 (KR) 10-2008-0100073

(51) Int. Cl. H01L 29/72; H01L 21/331

(52) U.S. Cl. 257/588; 438/367; 257/E21.37; 257/E29.173

(57) ABSTRACT

A bipolar transistor includes an isolation layer formed in a bipolar region on a semiconductor substrate, a conductive film formed over an upper portion of the isolation layer, n+ and p+ junction regions formed within the conductive film, a first silicide film formed over portions of an upper boundary of the n+ and p+ junction regions, the first silicide film defining openings over the upper boundary of the n+ and p+ junction regions, a second silicide film formed in the openings defined by the first silicide film over the upper boundary portions of the n+ and p+ junction regions, a plurality of plugs connected to the second silicide film, and a plurality of electrodes connected to each of the plugs. In this way, embodiments not only suppress the occurrence of parasitic junction between wells, but also simplify the processes by omitting well processes by forming an isolation layer in a bipolar region, forming a conductive film, and applying ion-implantation process to the conductive film to form a junction region.

The present application claims priority under 35 U.S.C. 119 to Korean Patent Application No. 10-2008-0100073 (filed on Oct. 13, 2008), which is hereby incorporated by reference in its entirety.

### BACKGROUND

Generally, bipolar junction transistors (BJT) are superior to metal oxide semiconductor (MOS) transistors in terms of performance, speed and gain. Thus, BJTs are used for designs of analog circuits, power circuits and radio frequency integrated circuits (RF IC).

However, a bipolar-CMOS-DMOS (BCD) process, taking advantage of BJT and complementary metal-oxide semiconductor (CMOS) processes, has high process costs due to its complexity. A BCD process, as a power integration technology, integrates bipolar and CMOS devices, used as logic circuits, with double diffused MOS (DMOS), used as power devices. Here, DMOS means a metal-oxide semiconductor field-effect transistor (MOSFET) manufactured using a double diffused process used as a high-voltage power device.

Hereinafter, a bipolar transistor fabricating process will be described with reference to the accompanying drawings. FIGS. 1A to 1F are cross sectional views illustrating a fabricating process of pnp bipolar transistor.

As illustrated in FIG. 1A, a local oxidation of silicon (LOCOS) process is performed to form an isolation layer 102 on a p-type semiconductor substrate 100. Next, as illustrated in FIG. 1B, n-type impurity ions are implanted in a low concentration into a specific region on the p-type semiconductor substrate 100. By adjusting ion implantation energy, the impurity ions are implanted more deeply than the isolation layer 102, thereby forming a n-well 104.

P-type impurity ions are implanted in a low concentration into a portion of the p-type semiconductor substrate 100 where the n-well is not formed. The p-type impurity ions are also implanted more deeply than the isolation layer 102 by adjusting ion implantation energy, thereby forming a p-well 106. The process for forming n-well and p-well may alternatively be performed in a contrary order.

As illustrated in FIG. 1C, p-type impurity ions are implanted in a high concentration into a specific region of the n-well 104 and the p-well 106 to form a shallow p+ junction. The p+ junction which is formed in the n-well 104 is an emitter region 108, and the p+ junction which is formed in the p-well 106 is a collector region 110. Next, n-type impurity ions are implanted in a high concentration into a specific region on the semiconductor substrate 100 where the emitter region 108 and the n-well 104 divided by the isolation layer 102 are formed to form a shallow n+ junction. The n+ junction is a base region 112. The process of implanting p-type impurity ions in a high concentration and the process of n-type impurity ions in a high concentration may be performed in a contrary order.

As illustrated in FIG. 1D, p-type impurity ions with a high concentration are reimplanted into the emitter region 108 and collector region 110, such that the emitter region 108 and collector region 110 extend more deeply into the semiconductor substrate 100. The ion implantation energy is adjusted not to allow the expanded emitter region 108 and collector region 110 to extend under the isolation layer 102.

As illustrated in FIG. 1E, n-type impurity ions with a high concentration are reimplanted into the base region 112, such that the base region 112 extends more deeply into the semiconductor substrate 100. The ion implantation energy is adjusted to prevent the base region 112 from extending under the isolation layer 102.

As illustrated in FIG. 1F, an insulating film 114 is formed Over entire surface of the semiconductor substrate 100. Thereafter, by selectively removing portions of the insulating film 114, a contact holes are formed exposing the emitter region 110, the collector region 110 and the base region 112. The contact holes are filled with a conductive material to form a plug 116, and an electrode layer is formed over entire surface of the semiconductor substrate 100.

Subsequently, the electrode layer is selectively removed, and as a result, the patterned electrode layer remains on the plug 116 and on its adjacent insulating film 114. Therefore, an emitter electrode 108a, a collector electrode 110a, and a base electrode 112a are formed electrically connected to the emitter region 108, the collector region 110, and the base region 112, respectively. From the above process, a PNP bipolar transistor is completed.

However, since the method of fabricating the PNP bipolar transistor requires a number of well processes using a CMOS processor, a parasitic junction between wells may occur, thereby reducing the gain and stability of the bipolar transistor.

### SUMMARY

Embodiments relate to a method for fabricating a semiconductor device, and, more particularly, to a bipolar transistor and method for fabricating the same capable of suppressing parasitic junction between wells.

Embodiments relate to a method which forms an isolation layer in a bipolar region, forms a conductive film, and forms junction regions by applying ion-implantation process to the conductive film.

Embodiments relate to a bipolar transistor, including an isolation layer formed in a bipolar region on a semiconductor substrate, a conductive film formed over an upper portion of the isolation layer, n+ and p+ junction regions formed within the conductive film, a first silicide film formed over portions of an upper boundary of the n+ and p+ junction regions, the first silicide film defining openings over the upper boundary of the n+ and p+ junction regions, a second silicide film formed in the openings defined by the first silicide film over the upper boundary portions of the n+ and p+ junction regions, a plurality of plugs connected to the second silicide film, and a plurality of electrodes connected to each of the plugs.

Embodiments relate to a method of fabricating bipolar transistor, including forming an isolation layer in a bipolar region on a semiconductor substrate, forming a conductive film over the isolation layer, and forming n+ and p+ junction regions within the conductive film.

The method of fabricating bipolar transistor further includes forming a metal layer over the semiconductor substrate, including the n+ and p+ junction regions, to form a first silicide film, patterning the first silicide film to open some of upper portions of the n+ and p+ junction regions, and forming a second silicide film over some of upper portions of the n+ and p+ junction regions.

Embodiments relate to an apparatus which may be configured to form an isolation layer in a bipolar region on a semiconductor substrate, form a conductive film over the isolation layer and form n+ and p+ junction regions within the conductive film. The apparatus may be further configured to form a metal layer over the semiconductor substrate, including the n+ and p+ junction regions, to form a first silicide film, pattern the first silicide film to open some of upper portions of the n+ and p+ junction regions, and form a second silicide film over some of upper portions of the n+ and p+ junction regions.

### DRAWINGS

FIGS. 1A to 1F are cross sectional views illustrating a fabricating process of pnp bipolar transistor.

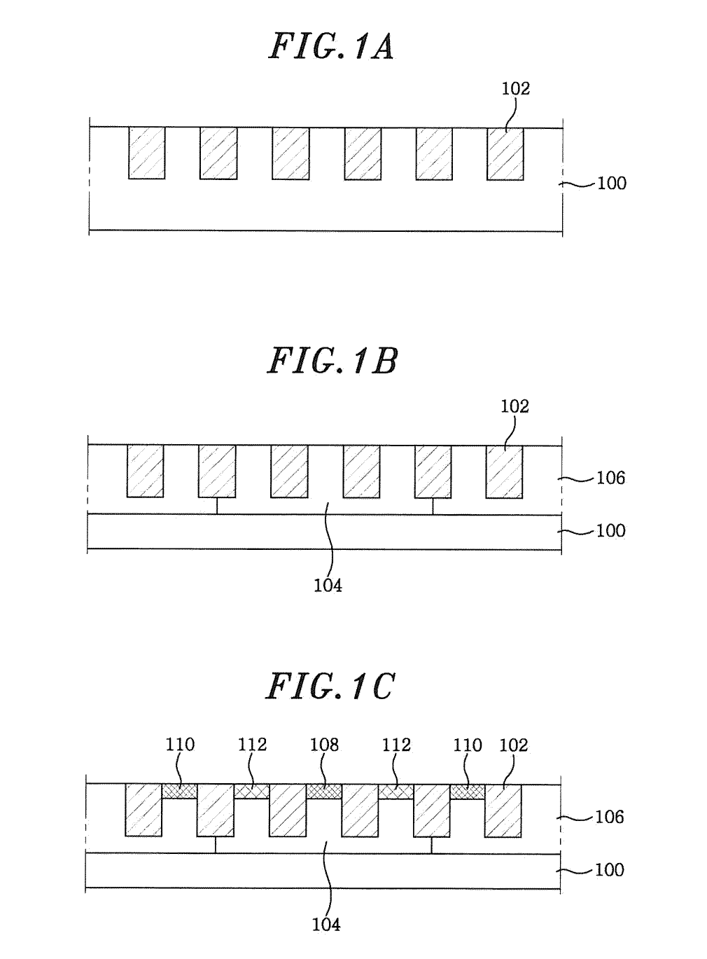

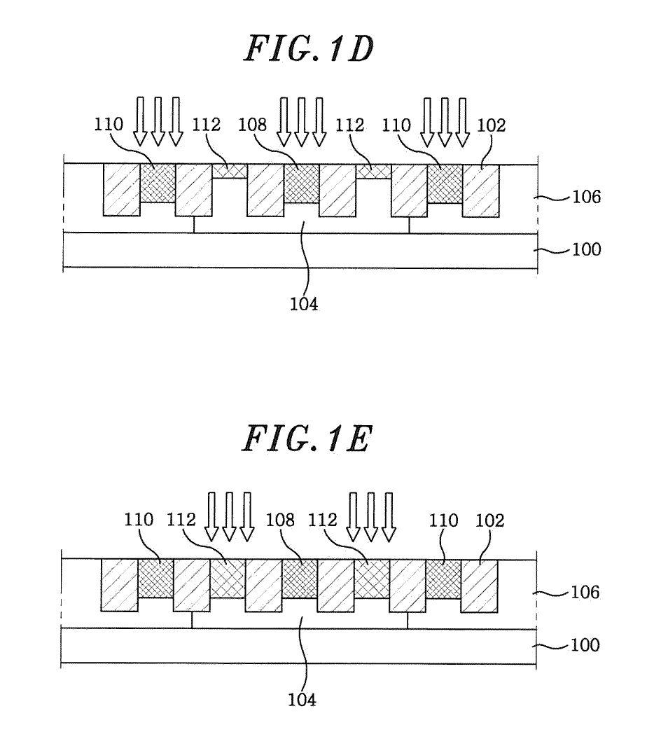

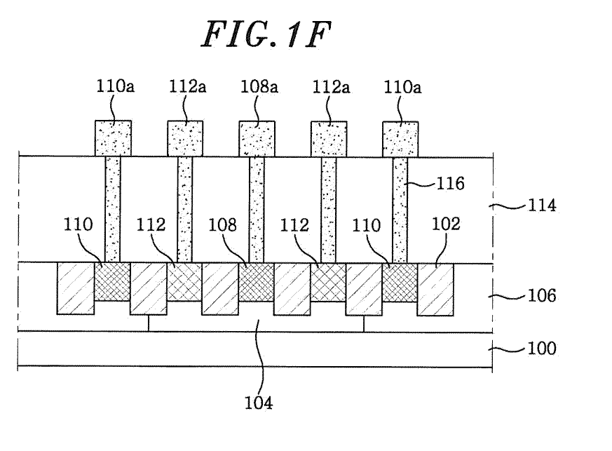

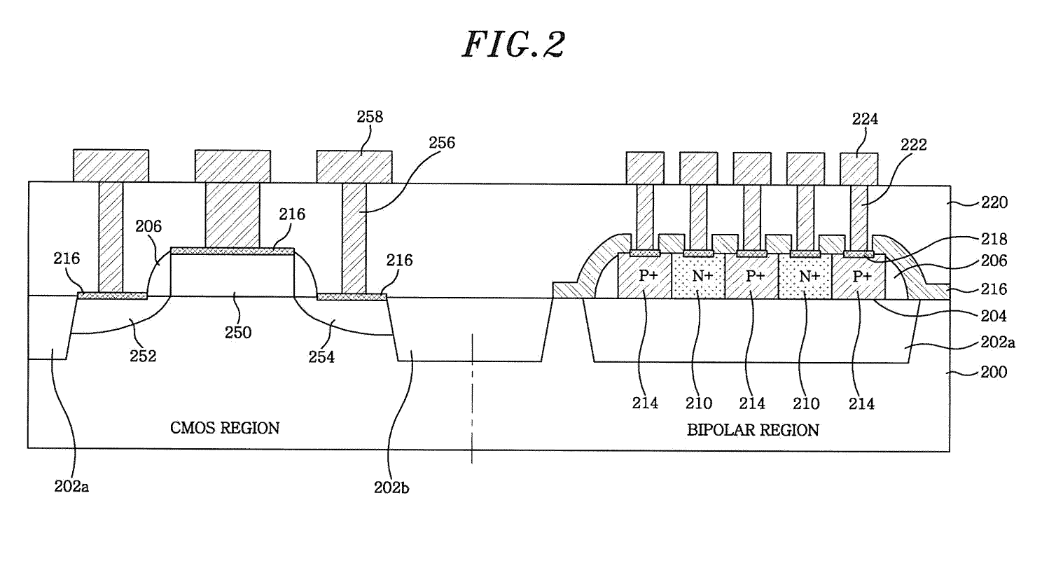

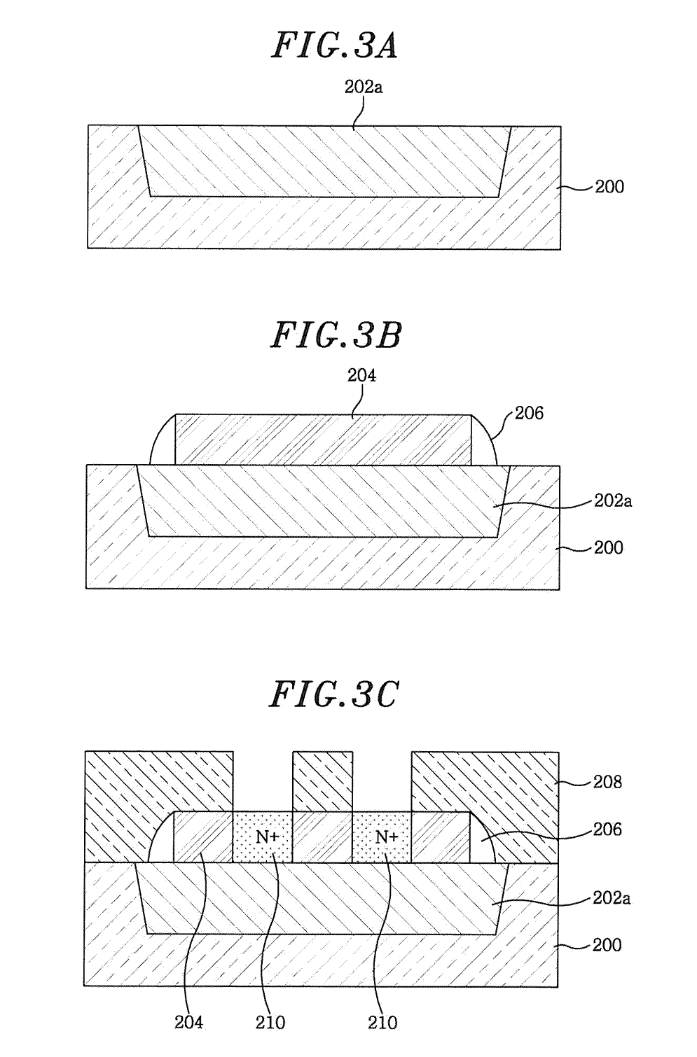

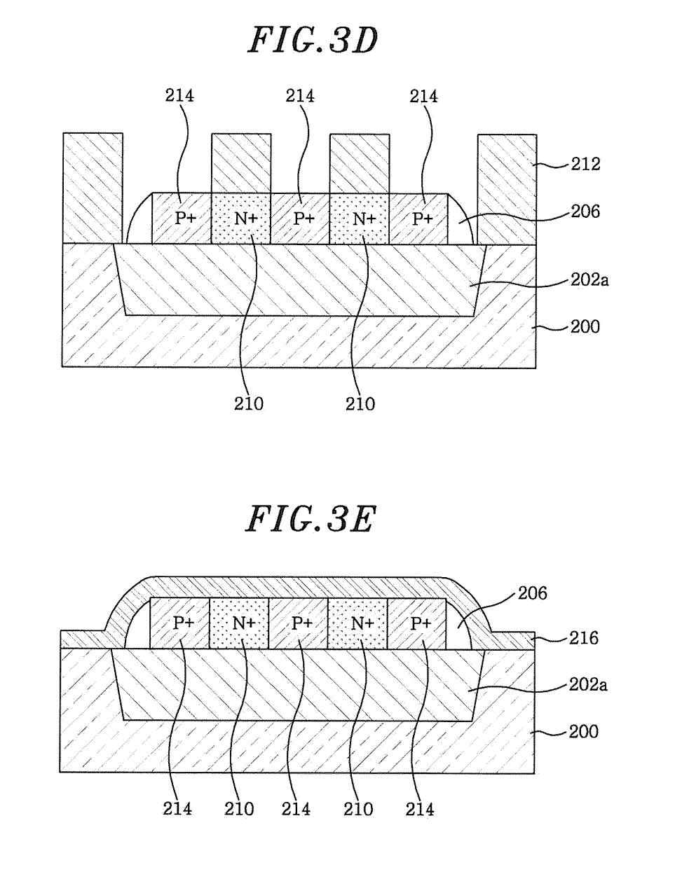

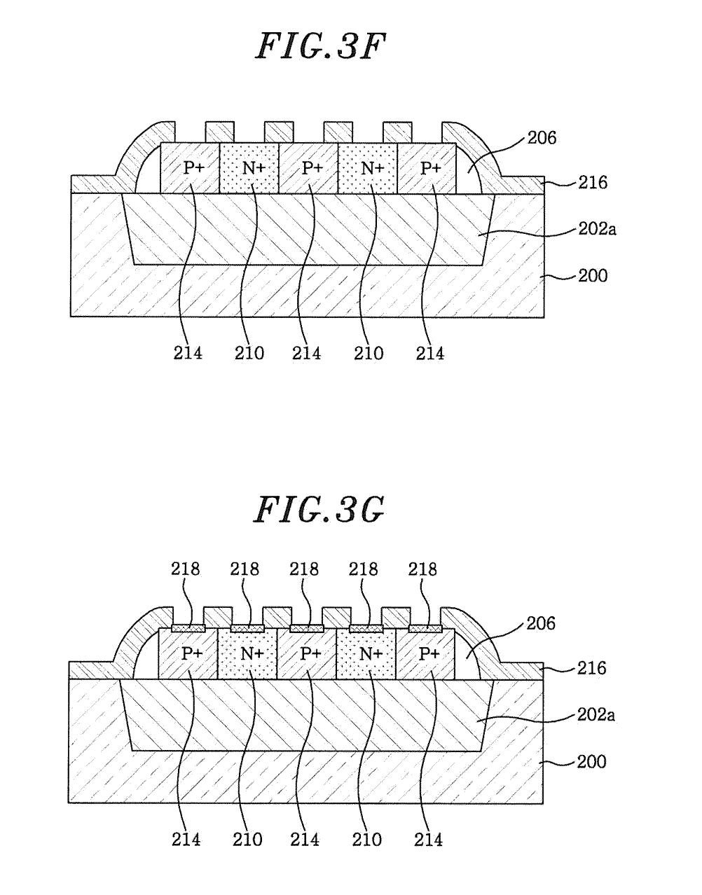

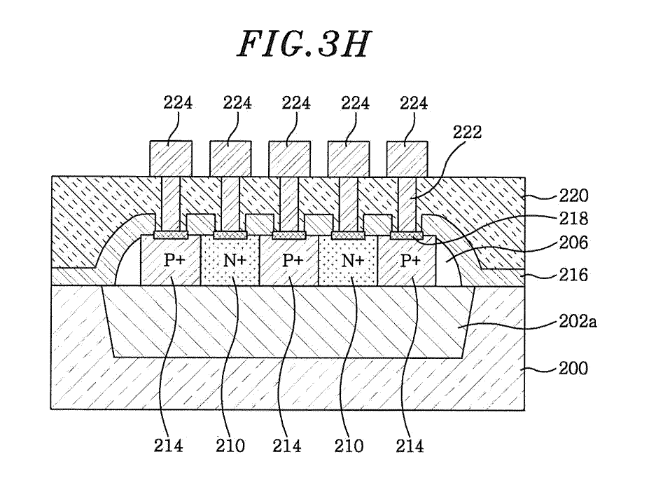

Example FIG. 2 is a cross sectional view of a semiconductor device having a bipolar transistor according to embodiments.

Example FIGS. 3A to 3H are cross sectional views illustrating a process of forming a bipolar transistor according to embodiments.

### DESCRIPTION

In embodiments, a bipolar transistor and its fabricating method will be explained, which suppress the occurrence of parasitic junction between wells. Example FIG. 2 is a cross sectional view of a semiconductor device having a bipolar transistor according to embodiments.

Referring to example FIG. 2, a bipolar region may include a trench-type isolation layer 202a which is formed in the bipolar region on a semiconductor substrate 200, and may include a conductive film 204 formed over the trench-type isolation layer 202a. Also, the bipolar region may include P+ and n+ junction regions which are formed in the conductive film 204 through impurity ion-implantation processes. Here, using the ion-implantation processes, n-type and p-type impurities may be alternately implanted into the conductive film 204. Additionally, a first silicide film 216 may be formed over the conductive film 204 except portions of upper boundary of the P+ and n+ junctions. A second silicide film 218 may also be formed the upper boundary portions of the P+ and n+ junctions. The bipolar region may also include an interlayer insulating film 220 in which a number of plugs 222 are formed, and may include electrodes 224 which are connected to the plugs 222.

Meanwhile, a CMOS region may include an isolation layer 202b for defining an active region, a gate electrode 250 which is formed in the active region, and a source/drain 252/254 which are respectively formed on either side of the gate electrode 250. A first silicide film 216 may also be included and formed over an upper portion of the gate electrode 250 and an upper portion of the source/drain 252/254. The CMOS region may also include contacts 258 connecting the first silicide film 216 with a metal wire 256. In embodiments, spacers 206 may be formed over sidewalls of the conductive film 204 and the gate electrode 250.

A process of forming a bipolar transistor with the above structure will be explained below. Example FIGS. 3A to 3H are cross sectional views illustrating a process of forming a bipolar transistor according to embodiments.

Referring to example FIG. 3A, a trench-type insulation layer 202a may be formed in a bipolar region of a semiconductor substrate 200. Here, the trench-type insulation layer 202a may be used for forming n+, p+ junction regions. The trench-type insulation layer 202a may be formed through a shallow trench isolation (STI) process, which is an isolation process for defining an active region in a CMOS region.

As illustrated in example FIG. 3B, a conductive material may be formed over the entire surface of the semiconductor substrate 200. A patterning process may be performed for this conductive material to form a gate electrode 250 in the active region of the CMOS region. The patterning process may also form a conductive film 204 for forming junction regions over an upper portion of the trench-type insulation layer 202a. Thereafter, spacers 206 may be formed over sidewalls of the gate electrode 250 and sidewalls of the conductive film 204 at the same time. Specifically, the spacers 206 may be formed according to the following steps. First, a conductive material, e.g. undoped polysilicon, may be formed and selectively etched to form a gate in the CMOS region as well as form the conductive film 204 over an upper portion of the trench-type insulation layer 202a. Next, an isolation layer may be formed over the gate and the conductive film 204. The isolation layer may be etched to form the spacers 206 over both sidewalls of the gate electrode 250 and both sidewalls of the conductive film 204.

Referring to example FIG. 3C, a first photoresist pattern 208 may be formed having opened regions for implanting n-type impurity ion. An ion-implantation process may be applied to the first photoresist pattern 208 using an ion-implantation mask to implant n-type impurity ion into opened portions of the conductive film 204, thereby forming n+ junction regions 210 in the conductive film 204.

Referring to example FIG. 3D, the first photoresist pattern 208 may be removed by performing a stripping process. A second photoresist pattern 212 may be formed over upper portions of the conductive film 204, except the n+ junction regions 210. An impurity ion-implantation process may be applied to the second photoresist pattern 212 using an impurity ion-implantation mask to implant impurity ion into the conductive film 204, thereby forming p+ junction regions 214. Before forming the n+ junction regions 210 and the p+ junction regions 214 described above, source/drain 252/254 may be formed over the semiconductor substrate 200 exposed by the spacers 206 in the CMOS region.

Referring to example FIG. 3E, the second photoresist pattern 212 may be removed and a metal layer may be formed thereon. An annealing process may be performed on the metal layer to form a first silicide film 216. The first silicide film 216 in the bipolar region may be formed together with the first silicide film 216 in the CMOS region.

In order to prevent the n+ junction regions 210 and the p+ junction regions 214 from shorting each other by the first silicide film 216, referring to example FIG. 3F, the first silicide film 216 may be selectively etched to open some portions of the n+ junction regions 210 and the p+ junction regions 214. In other words, an etching process may be performed using an etching mask which is formed over an upper portion of the first silicide film 216 to selectively etch the first silicide film 216, thereby opening some portions of the n+ junction regions 210 and the p+ junction regions 214.

Referring to example FIG. 3G, a second silicide film 218 may be formed over the opened portions of the n+ junction regions 210 and the p+ junction regions 214, through a salicide process. Referring to example FIG. 3H, an interlayer insulating film 220 may be formed and selectively etched to form contact holes exposing the second silicide film 218. Then, the contact holes may be filled with a conductive material to form plugs 222. Thereafter, an electrode layer may be formed over the entire surface of the semiconductor substrate 200 where plugs 22 are formed.

The electrode layer may be selectively removed to form electrodes 224, which electrically connect the n+ junction regions 210 with the p+ junction regions 214. In this way, pnp bipolar transistor is completed.

According to embodiments, processes can be simplified and deterioration of device characteristics due to the occurrence of parasitic junctions can be prevented, by forming junction regions in a conductive film 204 which is formed over an upper portion of trench-type isolation layer 202b in a bipolar region.

Embodiments form an isolation layer in a bipolar region, form a conductive film, and apply ion-implantation process to the conductive film to form a junction region. Through the above process, embodiments not only suppress the occurrence of parasitic junctions between wells but also simplify the processes by omitting well processes.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
an isolation layer formed in a bipolar region on a semiconductor substrate;
a conductive film formed over an upper portion of the isolation layer;
n+ and p+ junction regions formed within the conductive film;
a first silicide film formed over portions of an upper boundary of the n+ and p+ junction regions, the first silicide film defining openings over the upper boundary of the n+ and p+ junction regions;
a second silicide film formed in the openings defined by the first silicide film over the upper boundary portions of the n+ and p+ junction regions;
a plurality of plugs connected to the second silicide film; and
a plurality of electrodes connected to each of the plugs.

2. The apparatus of claim 1, wherein the isolation layer is formed in a shallow trench defined by the semiconductor substrate.

3. The apparatus of claim 1, wherein the conductive film is formed with undoped polysilicon.

4. The apparatus of claim 1, wherein the n+ and p+ junction regions are impurity ion-implantation regions.

5. The apparatus of claim 1, including:
spacers formed over both sidewalls of the conductive film.

6. The apparatus of claim 1, including:
an interlayer insulating film formed over the first and second silicide layers, wherein the plugs are formed in holes defined by the interlayer insulating film.

7. A method comprising:
forming an isolation layer in a bipolar region on a semiconductor substrate;
forming a conductive film over the isolation layer using an undoped polysilicon; and
forming n+ and p+ junction regions within the conductive film.

8. The method of claim 7; including:
forming a metal layer over the semiconductor substrate, including the n+ and p+ junction regions, to form a first silicide film;
patterning the first silicide film to open some of upper portions of the n+ and p+ junction regions; and
forming a second silicide film over some of upper portions of the n+ and p+ junction regions.

9. The method of claim 7, including:
forming spacers over both sidewalls of the conductive film after said forming the conductive film and before said forming n+ and p+ junction regions.

10. The method of claim 8, wherein the first silicide film is formed using an annealing process.

11. The method of claim 8, wherein the second silicide film is formed using a salicide process.
